(19) United States
(12) Patent Application Publication
(10) Pub. No.: US 2025/0232081 A1
(43) Pub. Date: Jul. 17, 2025

(54) PARTS ASSIGNMENT SYSTEM

(71) Applicant: HANWHA PRECISION MACHINERY CO., LTD., Changwon-si (KR)

(72) Inventors: Chul Eun SEO, Changwon-si (KR); Na Youn LEE, Changwon-si (KR)

(73) Assignee: HANWHA PRECISION MACHINERY CO., LTD., Changwon-si (KR)

(21) Appl. No.: 18/705,424

(22) PCT Filed: Apr. 19, 2022
(86) PCT No.: PCT/KR2022/005561

§ 371 Date: Apr. 26, 2024

(30) Foreign Application Priority Data
Dec. 23, 2021 (KR) 10-2021-0186604

(51) Int. Cl. G06F 30/20

(52) U.S. Cl. CPC G06F 30/20

(57) ABSTRACT

In a parts distribution system according to an embodiment of the present disclosure, parameter values for parts distributed to each gantry are input to an objective function (F(x)), and parts are distributed by searching for a best value that minimizes a value of the objective function through the parts distributed to each gantry.

### TECHNICAL FIELD

Embodiments of the present disclosure relate to a parts distribution system capable of distributing optimal parts to each mounting device in a production line consisting of a plurality of mounting devices.

### BACKGROUND ART

With the development of information and communication technology, more and more diverse parts are being installed on boards that make up electronic products. Accordingly, more parts mounting devices are being deployed on board production lines.

Therefore, to improve the efficiency of board production, more efficient task allocation to multiple mounting devices is needed.

Conventionally, parts are simply distributed to a plurality of mounting devices, based on part sizes, and part redistribution and mount sequence generation processing, which takes execution time, are performed each time, so there is a limit to the search for optimal parts distribution due to a limit on the total execution time that a user may wait for. Therefore, it is necessary to improve the efficiency of parts distribution by minimizing the repetitive performance of mount sequence generation and establishing an optimal parts distribution system.

### DISCLOSURE

### Technical Problem

According to one aspect of the present disclosure, the main task is to focus on an initial distribution of parts and minimize repetitive execution of redistribution and mount sequence generation execution to obtain optimal parts distribution results in a faster time.

However, these problems are illustrative, and the problems to be solved by the present disclosure are not limited thereto.

### Technical Solution

A parts distribution system according to an embodiment of the present disclosure wherein parameter values for parts distributed to each gantry of each of at least one electronic part mounting device of an in-line system including the at least one electronic part mounting device are input to an objective function (F(x)), the objective function includes a penalty weight and a reward weight, and parts are distributed by searching for a best value that minimizes a value of the objective function through the parts distributed to each gantry.

The penalty weight may be a value obtained by multiplying a number of collisions of all parts assigned to a gantry by a weight, a value obtained by multiplying a maximum distance of coordinates of a mounting point for each gantry by a weight, a value obtained by multiplying a total sum of numbers of types of nozzles for each gantry by a weight, and a value obtained by multiplying a number of feeder size violations and a number of nozzle size violations by a weight, and the reward weight may be a value obtained by multiplying a total sum of numbers of front and rear split feeders of partial twin equipment by a weight.

The objective function may be

$$F ( x ) = Min [ {max}_{i = 1 .. n} [ {\sum }_{k = 1}^{n} \vert {GT}_{i} - {LT}_{i} \vert + ( {R}_{k} * {W}_{r} ) + ( {D}_{k} * {W}_{d} ) + ( {N}_{k} * {W}_{n} ) - ( {F}_{k} * {W}_{f} ) ] + ( {V}_{k} * {W}_{m} ) ]$$

In the |GTᵢ−LTᵢ|, the GTᵢ may be a gantry time, and the LTᵢ is a load time.

The LTᵢ may be

$${LT}_{i} = [ {\sum }_{j = 1}^{n} {P}_{j} ( n ) * {W}_{s} * {UT}_{j} ] .$$

In the objective function, the penalty weight may be and, and the reward weight may be (Rₖ*Wᵣ)+(Dₖ*W_{d})+(Nₖ*Wₙ) and (Vₖ*Wₘ).

The best value that minimizes the value of the objective function is searched for based on a tabu search method.

The at least one electronic part mounting device has at least one gantry.

A parts distribution method according to an embodiment of the present disclosure includes setting a tabu list and aspiration criteria, and defining, as a best value, a value obtained by applying content of a current parameter to an objective function; generating a plurality of candidate solutions; sorting the plurality of candidate solutions in order; comparing a value output by sequentially inputting parameters of the plurality of sorted candidate solutions to the objective function with the best value to determine whether a better value exists; and when it is determined that the better value exists, defining, as the best value, a value of the objective function to which a parameter of a candidate solution (i) of a corresponding order (i) is applied.

The parts distribution method further includes determining whether the candidate solution (i) is included in the tabu list; and determining whether the candidate solution (i) is included in the aspiration criteria, wherein, when it is determined that the candidate solution (i) is included in the tabu list and the aspiration criteria, the candidate solution (i) is input to the tabu list, an objective function F(candidate solution(i)) reflecting the candidate solution (i) is input to the aspiration criteria, and the candidate solution (i) is set as a current variable (x).

Other aspects, features and advantages other than those described above become apparent from the detailed description, claims and drawings for carrying out the disclosure below.

### Advantageous Effects

By executing an initial distribution by predicting a best value of an objective function without generating a mount sequence that takes a long execution time through a parts distribution complex optimization algorithm based on the tabu search method, the parts distribution system according to an embodiment of the present disclosure has the effect of deriving optimal parts distribution results until distribution is completed through quick search that may minimize the time required to redistribute parts.

The effects of the present disclosure are not limited to the effects mentioned above, and other effects not mentioned are be clearly understood by one of ordinary skill in the art from the description of the claims.

### DESCRIPTION OF DRAWINGS

FIG. 1 is a diagram showing an input/output process of allocating parts and mounting points to a plurality of mounting devices through only one layer step, according to an embodiment of the present disclosure.

FIG. 2 is a schematic diagram showing an overall flow of a parts distribution system, according to an embodiment of the present disclosure.

FIG. 3 is a flowchart showing a parts distribution method reflecting a tabu search method, according to an embodiment of the present disclosure.

### BEST MODE

Because the present disclosure may be modified in various ways and may have various embodiments, specific embodiments are illustrated in the drawings and described in detail in the description of the disclosure. However, this is not intended to limit the present disclosure to specific embodiments, and should be understood to include all transformations, equivalents, and substitutes included in the idea and technical scope of the present disclosure. In describing the present disclosure, the same identification numbers are used for the same components even if they are shown in different embodiments.

Hereinafter, embodiments of the present disclosure are described in detail with reference to the attached drawings, and when describing with reference to the drawings, identical or corresponding components are given the same reference numerals and the descriptions already given are omitted.

In the following embodiments, terms, such as first and second are used not in a limiting sense but for the purpose of distinguishing one component from another component.

In the following examples, singular terms include plural terms unless the context clearly dictates otherwise.

In the following examples, terms, such as include or have mean that the features or components described in the specification exist, and do not exclude in advance the possibility of adding one or more other features or components.

In the drawings, the sizes of components may be exaggerated or reduced for convenience of explanation. For example, the size and thickness of each component shown in the drawings are shown arbitrarily for convenience of explanation, so the present disclosure is not necessarily limited to what is shown.

In cases where an embodiment may be implemented differently, a specific process sequence may be performed differently from the described sequence. For example, two processes described in succession may be performed substantially at the same time, or may be performed in an order opposite to that in which they are described.

The terms used in this application are only used to describe specific embodiments and are not intended to limit the disclosure. In this application, terms, such as “include” or “have” are intended to designate the presence of features, numbers, steps, operations, components, parts, or combinations thereof described in the specification, but should be understood as not precluding the presence or addition of one or more other features, numbers, steps, operations, components, parts, or combinations thereof.

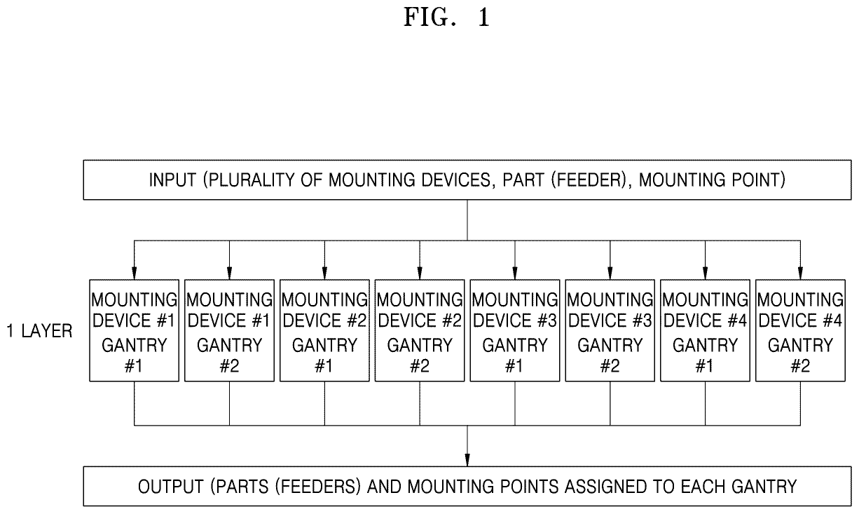

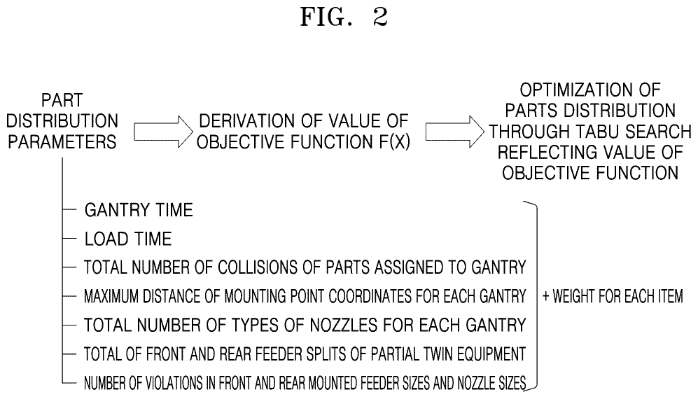

Hereinafter, a parts distribution system according to an embodiment of the present disclosure is described with reference to FIGS. 1 and 2.

FIG. 1 is a diagram showing an input/output process of allocating parts and mounting points to a plurality of mounting devices through only one layer step, according to an embodiment of the present disclosure. FIG. 2 is a schematic diagram showing an overall flow of a parts distribution system, according to an embodiment of the present disclosure.

Referring to FIGS. 1 and 2, the parts distribution system according to an embodiment of the present disclosure assigns parameters for parts allocated to each gantry as evaluation values using a tabu search method and distributes parts using an objective function in which the parameters are variable and reflected.

The parts distribution system according to this embodiment is system which allocates parts and mounting points to the gantries placed on each of the plurality of mounting devices through one layer may allocate parts and mounting points to each gantry with best results immediately upon initial part distribution without the need to redistribute the parts and mounting points assigned to the mounting device to the gantry, thereby significantly shortening the distribution time.

In the present disclosure, the mounting device may refer to a mechanical device that mounts various parts on the above-described board. In other words, the mounting device may be a device that performs the task of mounting electronic parts of various types and sizes, such as integrated circuits, high-density integrated circuits, diodes, condensers, and resistors, on a substrate, such as a printed circuit board. In this case, PCB work may be optimally distributed to multiple lines by considering the production time for each line. In other words, when there are multiple lines and the type of mounting device for each line is different, the production time of the entire line may be minimized by distributing the optimal PCB manufacturing parts to each line.

Additionally, feeder supply devices may be optimally distributed to lines with multiple mounting devices. In this case, the feeder supply device may be a reel, tray, stick, etc. In other words, when there are multiple lines and the type of mounting device for each line is different, various types of feeder supply devices may be distributed to the plurality of mounting devices in the optimal location and number.

Also, for example, when producing a plurality of PCBs, production sequence optimization scheduling may be performed to optimize the production sequence of multiple PCBs by having the operator determine the production sequence of multiple PCBs to minimize model changes.

According to this embodiment, the objective function F(x) may be defined as follows.

$$F ( x ) = Min [ {max}_{i = 1 .. n} [ {\sum }_{k = 1}^{n} \vert {GT}_{i} - {LT}_{i} \vert + ( {R}_{k} * {W}_{r} ) + ( {D}_{k} * {W}_{d} ) + ( {N}_{k} * {W}_{n} ) - ( {F}_{k} * {W}_{f} ) ] + ( {V}_{k} * {W}_{m} ) ]$$

In this case, the LTᵢ may be

$${LT}_{i} = [ {\sum }_{j = 1}^{n} {P}_{j} ( n ) * {W}_{s} * {UT}_{j} ]$$

Here, k is the board number (1, 2 . . . n), i is the gantry number (1, 2 . . . n), and j is the part number (1, 2 . . . n).

In this case, LTᵢ may be determined by Pⱼ(n) which is the total number of attachment points of the part j, UTⱼ, which is the speed level weight of the part, and the unit time-in for each attachment point of the part j.

Because the distribution speed of Wₛ, which is the speed level weight of part j, may vary depending on the type of part j, weights depending on the distribution speed of the part may be differentially applied. The speed weight Wₛ has 1 to 5 levels, and the speed weight Wₛ may be obtained by subtracting the speed level for each level from 5 and then multiplying the result of subtracting the speed by 0.1. For these details, Table 1 below is referred.

TABLE 1

| Ws | Speed level |
|---|---|
| (5-speed level)*0.1 | level 1 = 3.667 |
| | level 2 = 2.548 |
| | level 3 = 2.118 |
| | level 4 = 1.467 |
| | level 5 = 1.000 |

UTⱼ, which is the unit time for each mounting point of part j, means the time distributed for each mounting point of part j, and may be given a default value of 0.1. Additional weight may be given to the unit time UTⱼ depending on the specifications of the mounting device or the size of the part.

GTᵢ is gantry time, that is, the estimated time required to distribute parts to each gantry, and LTᵢ is load time, that is, the time allocated to each gantry. In this case, as shown in the objective function, it is necessary to shorten the time required for part distribution by minimizing the total difference between the gantry time and load time for each board and part.

In addition to the difference between the gantry time and the load time, the objective function according to this embodiment may include a penalty weight and a reward weight that may be required when distributing parts.

The penalty weight may be (Rₖ*Wᵣ)+(Dₖ*W_{d})+(Nₖ*Wₙ) and (Vₖ*Wₘ), and the compensation weight may be (Fₖ*W_{f}).

First, Rₖ may mean the total number of collisions of parts allocated to the gantry of the board k. When distributing parts, collisions between parts may occur depending on the width or height of the parts. Accordingly, when distributing parts, by minimizing the phenomenon of separation of mounting groups to increase the number of mounting groups between parts while minimizing the number of collisions between parts, part distribution time may be reduced and productivity according to parts distribution can be improved.

In this case, the value obtained by multiplying Rₖ by the weight Wᵣ of the number of part collisions may be applied to the function to ensure fairness with other weight values.

Next, Dₖ may mean the maximum distance of the mounting point coordinates for each gantry of board k. In other words, the closer the distance between the parts mounted on the mounting device, the faster the distribution. Therefore, by reflecting the maximum distance of the mounting point coordinates by referring to the coordinates of the head and tail of the parts, the maximum distance value of the mounting point coordinates may be minimized, thereby improving part distribution time and productivity.

In this case, the value obtained by multiplying Dₖ by the mounting point coordinate maximum distance weight W_{d} may be applied to the function to ensure fairness with other weight values.

And Nₖ may mean the total number of nozzle types for each gantry of board k. When distributing parts to the mounting device, the type of nozzle that distributes each part may also need to be different for each type of part, which may mean that the time required to distribute parts may vary depending on the type of nozzle. In this case, as the type of nozzle for distributing parts is reduced, the number of nozzles that need to be replaced for each part may be reduced, thereby improving part distribution time and productivity.

In this case, the value obtained by multiplying Nₖ by the weight Wₙ of the number of nozzle types may be applied to the function to ensure fairness with other weight values.

Fₖ may mean the total number of front and rear split feeders of the partial twin equipment of board k. In the case of partial duplex equipment, the parts of the feeder may be distributed together to the front and rear, which may improve the speed of parts distribution. Therefore, as the number of front and rear dual simultaneous distribution feeders through partial duplex equipment increases, part distribution time and productivity may be improved.

In this case, the value obtained by multiplying Fₖ by the feeder division weight W_{f} may be applied to the function to ensure fairness with other weight values.

In this way, according to this embodiment, the maximum value may be calculated considering the total sum of the differences between the gantry time and load time for each board and part in all gantries, as well as penalty weights and reward weights. After calculating this maximum value plus the product of Vₖ, which means the number of feeder size violations of board k and the number of nozzle size violations, and its weight Wₘ, the value that minimizes the added value may be a best value of the objective function.

As for the number of violations of Vₖ, the part distribution time may be shortened as the feeder distributing parts from the front is smaller than the feeder distributing parts from the back, but it may be defined as a violation when the size of the feeder placed in front is larger than the size of the feeder placed in the rear. Likewise, when the nozzle that distributes parts from the front is smaller than the nozzle that distributes parts from the back, the part distribution time may be shortened, but it may be defined as a violation when the size of the nozzle placed in front is larger than the size of the nozzle placed in the rear.

The above-described weight values (Wᵣ, W_{d}, Wₙ, W_{f}) may be experimental values. In other words, the final parameter value is defined by multiplying each parameter by the weight values, and because the importance of each parameter may be different, the degree of weighting for each parameter may be defined through the weight values. These weight values are defined as experimental examples and may be defined as shown in Table 2 below.

TABLE 2

| weight | value |
|---|---|
| Wᵣ | 0.3 |
| W_{d} | 0.3 |
| Wₙ | 0.4 |
| W_{f} | 0.5 |

In addition to the disadvantage weight and compensation weight described above, a weight for the ratio of the number of rear lower mounting points to the number of front upper mounting points of the TB board combination equipment can be applied. Additionally, weighting may be applied by adding the board transport time to the two-stage mounting load time. Additionally, weights may be applied to boards with a large multi-board quantity.

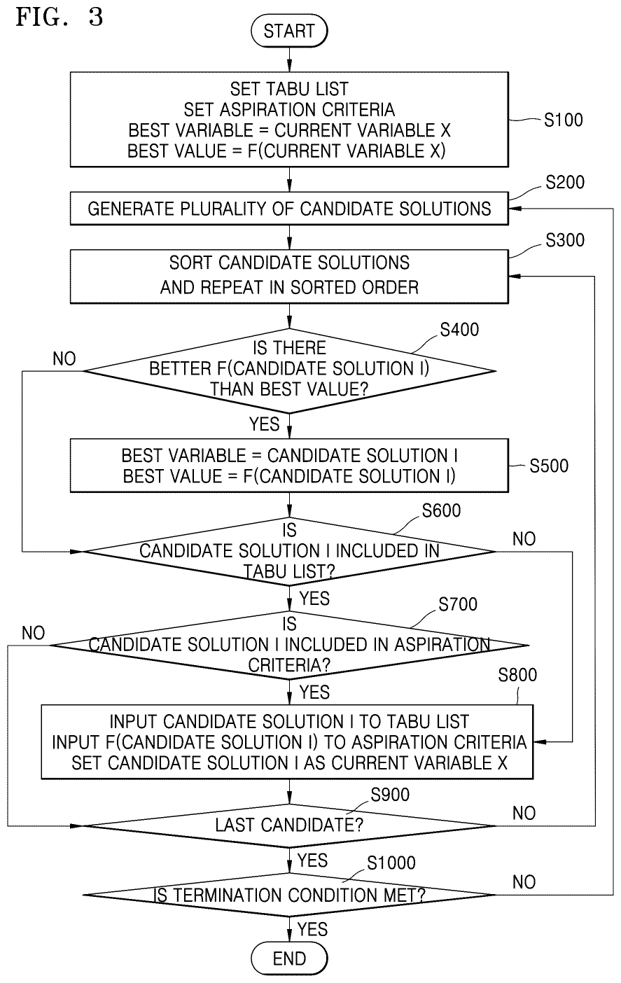

Hereinafter, a parts distribution method reflecting the tabu search method according to an embodiment of the present disclosure is described with reference to FIG. 3.

FIG. 3 is a flowchart showing the parts distribution method reflecting the tabu search method, according to an embodiment of the present disclosure.

Referring to FIG. 3, in the parts distribution method to which the tabu search method is applied, according to the present embodiment, the tabu search method may be used in a process of selecting a candidate solution that may have an optimal objective function among several candidate solutions whose objective functions may be derived in various ways.

Hereinafter, the parts distribution method that reflects the tabu search method is described. First, a tabu list for the parts distribution method that has been performed so far, that is, parts distribution histories, may be set, and aspiration criteria, which are conditions that may be improved in the future in parts distribution, may be set. In addition, in operation S100, a value obtained by applying the content of current distribution of parts, that is, the content of current parameters (variables), to the objective function may be defined as a best value.

Afterwards, in operation S200, a plurality of candidate solutions assuming parts distribution scenarios in various situations may be generated, and in operation S300, the candidate solutions may be sorted in order. An optimal candidate solution may be selected by judging the sorted candidate solutions sequentially. The candidate solution may refer to a situation in which a case where each parameter according to parts distribution is set and may be input to the objective function is set. The plurality of candidate solutions may be set as a candidate solution for the current parameter (variable) and an adjacent neighboring candidate solution, that is, a neighboring solution.

When judging the sorted candidate solutions sequentially, the parts distribution method may include operation S400, which is an operation of determining whether a better value exists by comparing a value (F(candidate solution i)) output by inputting parameters of an i-th part distribution candidate solution to the objective function with the best value obtained by inputting the existing current parameters (variable) to the objective function. In this case, when it is determined that the better value exists by comparing the output value F(candidate solution i) with the best value obtained by inputting the existing current parameter (variable), a value of the objective function to which the parameter of the i-th part distribution candidate solution is applied may be defined as the best value, in operation S500.

When it is determined that the better value does not exist by comparing the output value (F(candidate solution i)) with the best value obtained by inputting the existing current parameter (variable), it may be determined whether a candidate solution i is included in the tabu list, in operation S600.

After the value of the objective function to which the parameter of the i-th part distribution candidate solution is applied is defined as the best value, it may be determined whether the candidate solution i defined as the best value is included in the tabu list, in operation S600.

When it is determined that the candidate solution i is not included in the tabu list upon determining whether the candidate solution i defined as the best value is included in the tabu list in operation S600, the candidate solution i is input into the tabu list, the objective function F(candidate solution i) reflecting the candidate solution i is input to the aspiration criteria, and the part distribution candidate solution i may be set as a current variable x, in operation S800.

When it is determined that the candidate solution i defined as the best value is included in the tabu list, it may be determined whether candidate solution i defined as the best value is included in the aspiration criteria, in operation S700.

When it is determined that the candidate solution i defined as the best value is included in the aspiration criteria, the candidate solution i may be input to the tabu list, and an objective function F(candidate solution i) reflecting the candidate solution i may be input to the aspiration criteria. Additionally, in operation S800, the parts distribution candidate solution i may be set to the current variable x.

In this case, when it is determined that the candidate solution i defined as the best value is not included in the aspiration criteria, it may be determined whether the candidate solution i is the last candidate solution, in operation S900.

In this way, among a plurality of candidate solutions, that is, adjacent solutions, the candidate solution from which the best value is derived when applied to the objective function F(x) is defined as the best value, and the best value is reflected in the part distribution method, and by continuously searching parts distribution conditions by including the candidate solution i from which the best value is derived in the tabu list and aspiration criteria, the parts distribution method may be continuously updated and optimized.

After the candidate solution i is input into the tabu list, the objective function F(candidate solution i) reflecting the candidate solution i is input to the aspiration criteria, and the part distribution candidate solution i is set to the current variable x, it may be determined whether the candidate solution i is the last candidate solution, in operation S900. When it is determined that the candidate solution i is not the last candidate solution, the parts distribution method proceeds again to the candidate solution sorting operation (operation S300), and judgment may be made on other candidate solutions. When the candidate solution i is the last candidate solution, it may be determined whether a termination condition is met, in operation S1000. When the termination condition is not met, the parts distribution method may start again from the operation of generating the plurality of candidate solutions (operation S200), and when the termination condition is met, the tabu search may be terminated.

The termination condition may be met when the total number of iterations of the tabu search reaches a given maximum number of iterations, or reaches a maximum number of iterations at which an optimal value is no longer generated from a candidate solution.

In this way, by assigning parameters to each evaluation value for the parts assigned to each gantry based on the tabu search method, a meta-heuristic algorithm, the present disclosure may be said to be a tabu search-based parts distribution complex optimization algorithm that searches to optimize parts distribution based on the value of the objective function such that the maximum of the evaluation values of all gantries is minimized; By allowing the optimal part distribution value to be predicted at the time of initial part distribution through the objective function value without generating a separate mount sequences that take a long time to execute each time the parts are delivered to each mounting device and gantry connected to each mounting device, when redistributing parts, parts distribution may be performed more efficiently.

Although the present disclosure has been described with reference to the embodiments shown in the drawings, these are merely examples. One of ordinary skill in the art may fully understand that various modifications and equivalent other embodiments are possible from the embodiments. Therefore, the true technical protection scope of the present disclosure should be determined based on the attached claims.

The specific technical content described in the embodiment is an example and does not limit the technical scope of the embodiment. In order to describe the disclosure concisely and clearly, descriptions of conventional general techniques and configurations may be omitted. In addition, the connection or connection member between the components shown in the drawings illustratively represent functional connections and/or physical or circuit connections, and may be represented by a variety of replaceable or additional functional connections, physical connections, or circuit connections in the actual device. Additionally, when there is no specific mention such as “essential,” “important,” etc., it may not be a necessary component for the application of the present disclosure.

“The” or similar designators used in the description and claims may refer to both the singular and the plural, unless otherwise specified. Additionally, when the range is described in the example, disclosures that apply individual values within the range are included (unless there is a statement to the contrary), and it is the same as describing each individual value constituting the range in the description of the disclosure. Additionally, unless there is an explicit ordering of the operations constituting the method according to the embodiment or a statement to the contrary, the operations may be performed in an appropriate order. The embodiments are not necessarily limited by the order of description of the operations above. The use of any examples or illustrative terms (e.g., etc.) in the embodiments is merely for describing the embodiments in detail, and unless limited by the claims, the scope of the embodiments is not limited by the examples or illustrative terms. Additionally, one of ordinary skill in the art appreciate that various modifications, combinations and changes may be made depending on design conditions and factors within the scope of the appended claims or their equivalents.

### INDUSTRIAL APPLICABILITY

According to an embodiment of the present disclosure, by using a parts distribution system and method, optimal part distribution and mounting sequence results for each mounting device may be obtained in a short time on a production line consisting of a plurality of mounting devices.

1. A parts distribution system, wherein parameter values for parts distributed to each gantry of each of at least one electronic part mounting device of an in-line system including the at least one electronic part mounting device are input to an objective function (F(x)), the objective function includes a penalty weight and a reward weight, and parts are distributed by searching for a best value that minimizes a value of the objective function through the parts distributed to each gantry.

2. The parts distribution system of claim 1, wherein the penalty weight is a value obtained by multiplying a number of collisions of all parts assigned to a gantry by a weight, a value obtained by multiplying a maximum distance of coordinates of a mounting point for each gantry by a weight, a value obtained by multiplying a total sum of numbers of types of nozzles for each gantry by a weight, and a value obtained by multiplying a number of feeder size violations and a number of nozzle size violations by a weight, and
wherein the reward weight is a value obtained by multiplying a total sum of numbers of front and rear split feeders of partial twin equipment by a weight.

3. The parts distribution system of claim 1, wherein the objective function is
$$F ( x ) = Min [ {max}_{i = 1 .. n} [ {\sum }_{k = 1}^{n} \vert {GT}_{i} - {LT}_{i} \vert + ( {R}_{k} * {W}_{r} ) + ( {D}_{k} * {W}_{d} ) + ( {N}_{k} * {W}_{n} ) - ( {F}_{k} * {W}_{f} ) ] + ( {V}_{k} * {W}_{m} ) ] .$$

4. The parts distribution system of claim 3, wherein, in the |GTᵢ−LTᵢ|, the GTᵢ is a gantry time, and the LTᵢ is a load time.

5. The parts distribution system of claim 4, wherein the LTᵢ is
$${LT}_{i} = [ {\sum }_{j = 1}^{n} {P}_{j} ( n ) * {W}_{s} * {UT}_{j} ] .$$

6. The parts distribution system of claim 3, wherein, in the objective function, the penalty weight is (Rₖ*Wᵣ)+(Dₖ*W_{d})+(Nₖ*Wₙ) and (Vₖ*Wₘ), and the reward weight is (Fₖ*W_{f}).

7. The parts distribution system of claim 1, wherein the best value that minimizes the value of the objective function is searched for based on a tabu search method.

8. The parts distribution system of claim 1, wherein the at least one electronic part mounting device has at least one gantry.

9. A parts distribution method comprising:
setting a tabu list and aspiration criteria, and defining, as a best value, a value obtained by applying content of a current parameter to an objective function;
generating a plurality of candidate solutions;
sorting the plurality of candidate solutions in order;
comparing a value output by sequentially inputting parameters of the plurality of sorted candidate solutions to the objective function with the best value to determine whether a better value exists; and
when it is determined that the better value exists, defining, as the best value, a value of the objective function to which a parameter of a candidate solution (i) of a corresponding order (i) is applied.

10. The parts distribution method of claim 9, further comprising
determining whether the candidate solution (i) is included in the tabu list; and
determining whether the candidate solution (i) is included in the aspiration criteria,
wherein, when it is determined that the candidate solution (i) is included in the tabu list and the aspiration criteria, and
wherein the candidate solution (i) is input to the tabu list, an objective function F(candidate solution(i)) reflecting the candidate solution (i) is input to the aspiration criteria, and the candidate solution (i) is set as a current variable (x).
